(19) United States
(12) Patent Application Publication
(10) Pub. No.: US 2025/0087532 A1
(43) Pub. Date: Mar. 13, 2025

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Kuang-Wei YANG, Hsinchu City (TW); Cheng-Chin LEE, Taipei City (TW); Shao-Kuan LEE, Kaohsiung City (TW); Jing Ting SU, Hsinchu City (TW); Hsin-Ning HUNG, New Taipei City (TW); Hsin-Yen HUANG, New Taipei City (TW); Hsiao-Kang CHANG, Hsinchu City (TW)

(73) Assignee: TAIWAN SEMICONDUCTOR MANUFACTURING COMPANY, LTD., Hsinchu (TW)

(21) Appl. No.: 18/465,583

(22) Filed: Sep. 12, 2023

(51) Int. Cl. H01L 21/768; H01L 23/528

(52) U.S. Cl. CPC H01L 21/76834; H01L 23/5283; H01L 21/76885

(57) ABSTRACT

A method includes forming a metal layer over a dielectric layer; forming hard masks over the metal layer; etching the metal layer using the hard masks as etch mask to form metal features; selectively forming dielectric liners on opposite sidewalls of each of the metal features, while leaving surfaces of the hard masks and the dielectric layer exposed by the dielectric liners; and forming an inter-metal dielectric layer laterally surrounding the metal features.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 11 illustrate a method in various stages of forming a semiconductor device in accordance with some embodiments of the present disclosure.

FIGS. 12 to 14 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

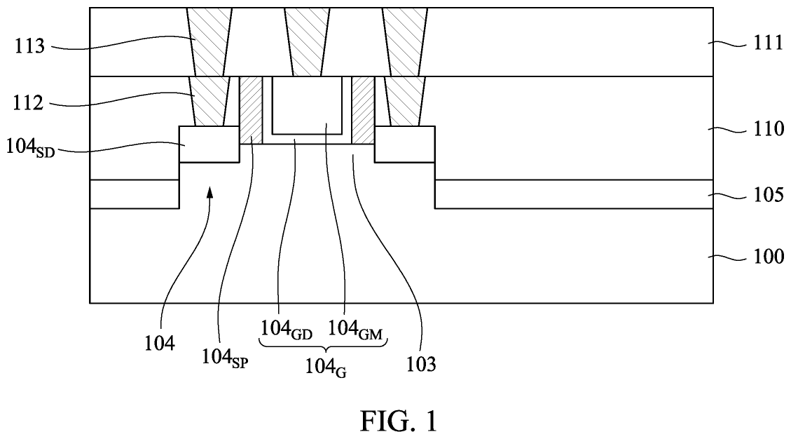

FIGS. 1 to 11 illustrate a method in various stages of forming a semiconductor device in accordance with some embodiments of the present disclosure. Although FIGS. 1 to 11 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

In some embodiments, one or more active and/or passive devices 104 (illustrated in FIG. 1 as a single transistor) are formed on the substrate 100. The one or more active and/or passive devices 104 may include various N-type metal-oxide semiconductor (NMOS) and/or P-type metal-oxide semiconductor (PMOS) devices, such as transistors, capacitors, resistors, diodes, photo-diodes, fuses, and the like. One of ordinary skill in the art will appreciate that the above examples are provided for the purpose of illustration only and are not meant to limit the present disclosure in any manner. Other circuitry may be also formed as appropriate for a given application.

In the depicted embodiments, the device 104 is a fin field-effect transistor (FinFET) that are three-dimensional MOSFET structure formed in fin-like strip of semiconductor protrusion referred to as fin 103. The cross-section shown in FIG. 1 is taken along a longitudinal axis of the fin in a direction parallel to the direction of the current flow between the source/drain regions 104_{SD}. The fin 103 may be formed by patterning the substrate 100 using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 103 by etching a trench into the substrate 102 using, for example, reactive ion etching (RIE). In some other embodiments, the device 104 may also be planar transistors or gate-all-around (GAA) transistors.

Shallow trench isolation (STI) regions 105 are formed on opposing sidewalls of the fin 103. The STI regions 105 may be formed by depositing one or more dielectric materials (e.g., silicon oxide) to completely fill the trenches around the fin and then recessing the top surface of the dielectric materials. The dielectric materials of the STI regions 105 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 105 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 105 such that an upper portion of fins 103 protrudes from surrounding insulating STI regions 105. In some cases, the patterned hard mask used to form the fin 103 may also be removed by the planarization process.

The device 104 includes a gate structure 104_{G} formed over the fin 103. In some embodiments, a gate structure 104_{G} of the device 104 illustrated in FIG. 1 is a high-k metal gate (HKMG) gate structure that may be formed using a gate-last process flow. In a gate-last process flow, a sacrificial dummy gate structure (not shown) is formed after forming the STI regions 105. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 105. As described in greater detail below, the dummy gate structure may be replaced by the metal gate structure 104_{G} as illustrated in FIG. 1. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

In FIG. 1, source/drain regions 104_{SD} and spacers 104_{SP} of the device 104 are formed, for example, self-aligned to the dummy gate structures. Spacers 104_{SP} may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 104_{SP} along the sidewalls of the dummy gate structures extending laterally onto a portion of the surface of the fin 103.

Source/drain regions 104_{SD} are semiconductor regions in direct contact with the semiconductor fin 103. In some embodiments, the source/drain regions 104_{SD} may comprise heavily-doped regions and relatively lightly-doped drain extensions, or LDD regions. Generally, the heavily-doped regions are spaced away from the dummy gate structures using the spacers 104_{SP}, whereas the LDD regions may be formed prior to forming spacers 104_{SP} and, hence, extend under the spacers 104_{SP} and, in some embodiments, extend further into a portion of the semiconductor fin 103 below the dummy gate structure. The LDD regions may be formed, for example, by implanting dopants (e.g., As, P, B, In, or the like) using an ion implantation process.

The source/drain regions 104_{SD} may comprise an epitaxially grown region. For example, after forming the LDD regions, the spacers 104_{SP} may be formed and, subsequently, the heavily-doped source and drain regions may be formed self-aligned to the spacers 104_{SP} by first etching the fins to form recesses, and then depositing a crystalline semiconductor material in the recess by a selective epitaxial growth (SEG) process that may fill the recess and may extend further beyond the original surface of the fin 103 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of dopants may be introduced into the heavily-doped source/drain regions 104_{SD} either in situ during SEG, or by an ion implantation process performed after the SEG, or by a combination thereof.

Once the source/drain regions 104_{SD} are formed, a first ILD layer 110 is deposited over the source/drain regions 104_{SD}. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD layer 110. The metal gate structures 104_{G}, illustrated in FIG. 1, may then be formed by first removing the dummy gate structures using one or more etching techniques, thereby creating recesses between respective spacers 104_{SP}. Next, a replacement gate dielectric layer 104_{GD} comprising one more dielectrics, followed by a replacement gate metal layer 104_{GM} comprising one or more metals, are deposited to completely fill the recesses. Excess portions of the gate dielectric layer 104_{GD} and gate metal layer 104_{GM} may be removed from over the top surface of first ILD layer 110 using, for example, a CMP process. The resulting structure, as illustrated in FIG. 1, may include remaining portions of the gate dielectric layer 104_{GD} and gate metal layer 104_{GM} inlaid between respective spacers 104_{SP}.

The gate dielectric layer 104_{GD} includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the gate metal layer 104_{GM} may be a multilayered metal gate stack comprising a barrier layer, a work function layer, and a gate-fill layer formed successively on top of gate dielectric layer 104_{GD}. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

Source/drain contacts 112 are formed in the first ILD layer 110 to make electrical connections to the source/drain regions 104_{SD} of devices 104. The source/drain contacts 112 may be formed using photolithography, etching and deposition techniques.

For example, a patterned mask may be formed over the first ILD layer 110 and used to etch openings that extend through the first ILD layer 110 to expose the source/drain regions 104_{SD}. Thereafter, conductive liner may be formed in the openings in the first ILD layer 110. Subsequently, the openings are filled with a conductive fill material. The liner comprises barrier metals used to reduce out-diffusion of conductive materials from the contacts 112 into the surrounding dielectric materials. In some embodiments, the liner may comprise two barrier metal layers. The first barrier metal may comprise Ti, Ni, Pt, Co, other suitable metals, or their alloys, and may form silicide with the source/drain regions 104_{SD}. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the first ILD layer 110.

After the source/drain contacts 112 are formed, a second ILD layer 111 is formed over the first ILD layer 110. In some embodiments, the insulating materials to form the first ILD layer and the second ILD layer may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer and the second ILD layer may be deposited using any suitable method, such as CVD, physical vapor deposition (PVD), ALD, PEALD, PECVD, SACVD, FCVD, spin-on, and/or the like, or a combination thereof.

Vias 113 are formed in the second ILD layer 111, in which some vias 113 are electrically connected to the source/drain contacts 112, and one of the vias 113 is electrically connected to the gate structure 104_{G}. The vias 113 may be formed using a similar method as the source/drain contacts 112, and thus relevant details will not be repeated for brevity. In some embodiments, the vias 113 in contact with the source/drain contacts 112 can be referred to as source/drain vias, and the via 113 in contact with the gate structure 104_{G} can be referred to as gate via.

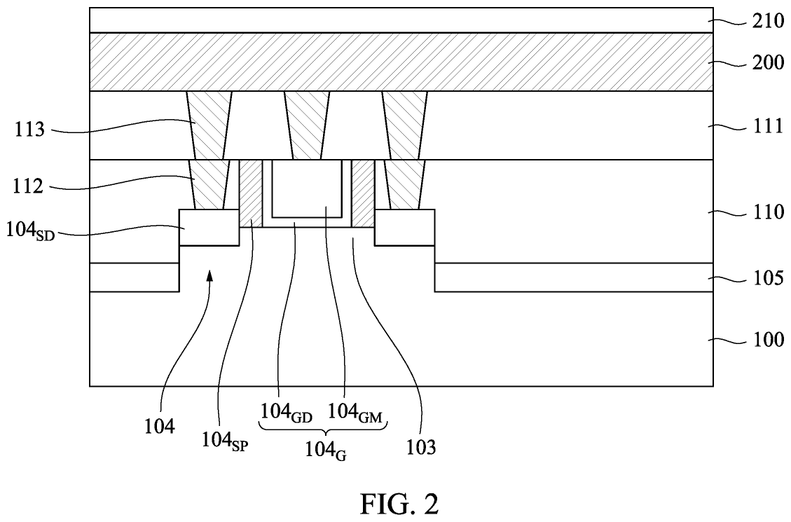

Reference is made to FIG. 2. A conductive layer 200 is formed over the second ILD layer 111, and a hard mask layer 210 is formed over the conductive layer 200. In some embodiments, material of the conductive layer 200 can include metal, such as Cu, Co, Ni, Ru, Ir, Pt, Rh, FeCo, FeAl, or other element or binary metals. In some embodiments, the hard mask layer 210 may include dielectric material, such as silicon nitride (SiNₓ), silicon oxide (SiO₂), combinations thereof, or other suitable dielectric materials. The thickness of the hard mask layer 210 is in a range from about 300 Å to about 500 Å. The conductive layer 200 may be formed by, for example, electrochemical plating (ECP), electroless deposition (ELD), PVD, or the like. In some embodiments, the hard mask layer 210 may be formed by, for example, PVD, PEALD, thermal-ALD, PECVD, or the like.

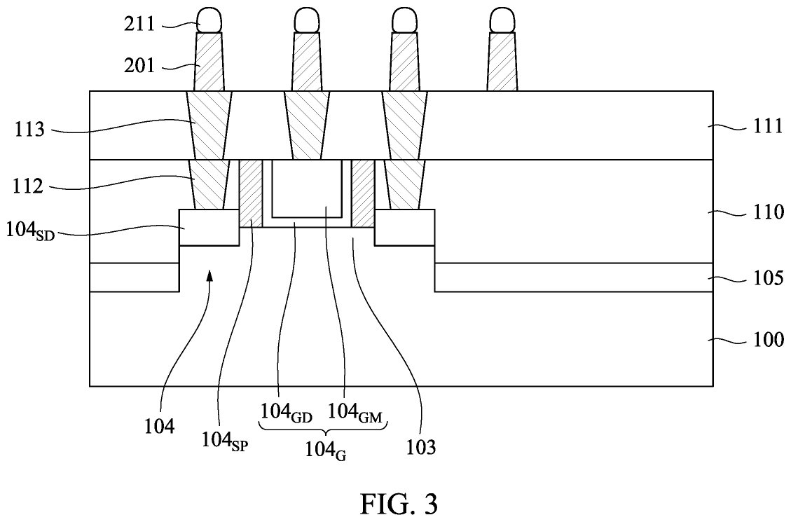

Reference is made to FIG. 3. The hard mask layer 210 is patterned to form a plurality of hard masks 211. In some embodiments, the hard mask layer 210 may be patterned by, for example, forming a patterned mask (e.g., photoresist) over the hard mask layer 210. The patterned mask may include openings exposing unwanted portions of the hard mask layer 210. Then, a first etching process is performed to remove the unwanted portions of the hard mask layer 210 by using the patterned mask as etch mask, and portions of the hard mask layer 210 protected by the patterned mask may remain over the conductive layer 200 and are referred to as the hard masks 211. After the first etching process is complete, the patterned mask is removed.

Afterwards, a second etching process is performed to remove portions of the conductive layer 200 by using the hard masks 211 as etch mask. In greater detail, portions of the conductive layer 200 exposed by the hard masks 211 are removed, and portions of the conductive layer 200 protected by the hard masks 211 may remain over the second ILD layer 111 and are referred to as conductive features 201. In some embodiments, the conductive features 201 may be in contact with the respective vias 113. The second etching process may include reactive-ion etching (RIE) or inductively coupled plasma RIE (ICP-RIE). In some embodiments where the second etching process is ICP-RIE, the etching condition includes TCP power in a range from 100 W to 1500 W, bias in a range from 0V to 300 B, and the etching gas may include CH₃COOH, CH₃OH, CH₃CH₂OH, or other suitable organic gas. In other embodiments, the etching condition includes TCP power in a range from 100 W to 1500 W, bias in a range from 0V to 300 B, and the etching gas may include CF₄, CHF₃, CH₃F, CH₂F₂, C₄F₈, C₄F₆, N₂, O₂ and Ar.

In some embodiments, each of conductive features 201 may include a trapezoid cross-sectional profile. That is, a width of the conductive feature 201 may decrease as a distance from the substrate 100 increases. Stated another way, a top surface of the conductive feature 201 is narrower than a bottom surface of the conductive feature 201. In some embodiments, the bottom surface of the conductive feature 201 may be narrower than a top surface of the corresponding via 113. Accordingly, portions of the top surfaces of the vias 113 may be exposed through the conductive features 201.

In some embodiments, the conductive features 201 may also be referred to as metal lines. Here, the term “metal line” may indicate that the structure (e.g., conductive features 201) has a longest dimension extending laterally. The “metal line” may be used to conduct current laterally and may be used to distribute electrical signals and power within one level.

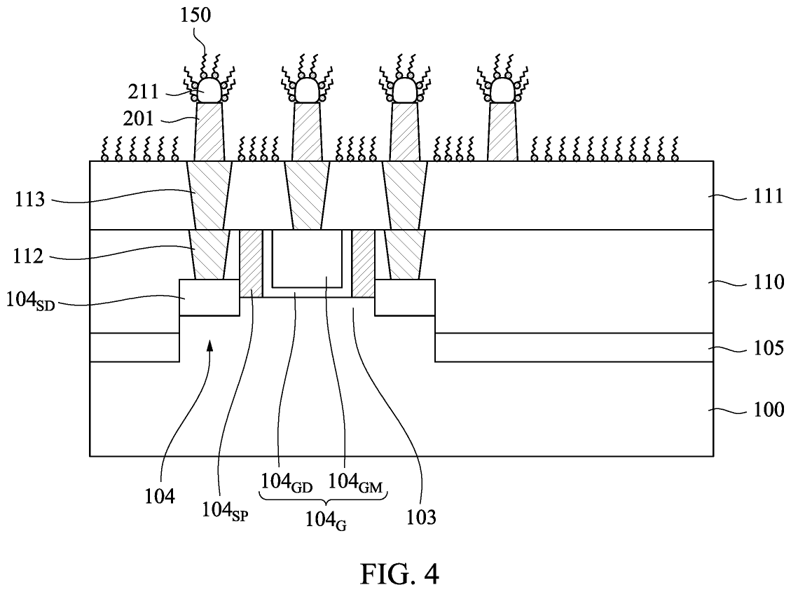

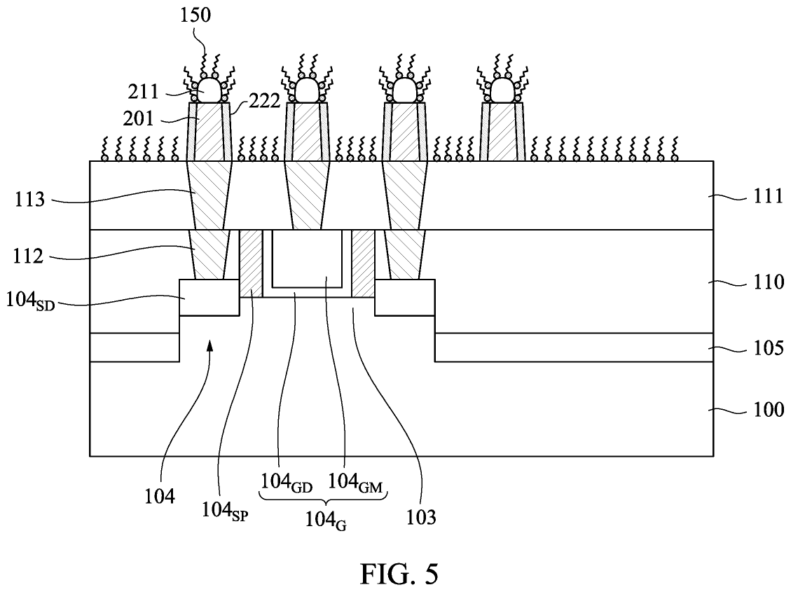

Reference is made to FIG. 4. A surface passivation process is performed to the exposed surfaces of the hard masks 211 and the second ILD layer 111. In greater detail, the surface passivation process is performed such that the exposed surfaces of the hard masks 211 and the second ILD layer 111 are passivated, while the exposed surfaces of the conductive features 201 may remain un-passivated. In some embodiments, the surface passivation process includes forming inhibitors 150 on the exposed surfaces of the hard masks 211 and the second ILD layer 111, while the exposed surfaces of the conductive features 201 may be free of coverage by the inhibitors 150. That is, after the surface passivation process is complete, the surfaces of the conductive features 201 remain exposed. The inhibitors 150 may be used to suppress growth rate of a material formed in later steps (e.g., the dielectric liners 222 in FIG. 5), and will be discussed later. In some embodiments, the inhibitors 150 may be formed by vapor phase deposition, such as CVD, or by wet deposition process, such as spin coating, spray, dip coating, or other suitable deposition process.

In some embodiments, the inhibitors 150 may include self-assembled-monolayer (SAM). For example, the SAM may include silanol or silyl halide headgroup and hydrocarbon backbone that can selective grown on dielectric surface. That is, SAM can be selectively formed on a dielectric surface (e.g., the hard masks 211 and the second ILD layer 111), but may not be formed on a metal surface (e.g., the conductive features 201). Stated another way, SAM may include higher growth rate on a dielectric surface than on a metal surface.

Reference is made to FIG. 5. Dielectric liners 222 are selectively formed on opposite sidewalls of each of the conductive features 201. This is because the inhibitors 150 may suppress the deposition rate (or growth rate) of the dielectric liners 222, and thus the dielectric liners 222 can be selectively formed on the exposed surfaces of the conductive features 201 which are free of coverage by the inhibitors 150. That is, the dielectric liners 222 may not be formed on the inhibitors 150. Stated another way, the dielectric liners 222 may not be formed on the passivated surfaces of the hard masks 211 and the second ILD layer 111, because such surfaces of the hard masks 211 and the second ILD layer 111 are coated with the inhibitors 150. In some embodiments, the dielectric liners 222 may be in contact with the respective vias 113.

In some embodiments, the dielectric liners 222 may include a dielectric material, such as SiOC, SiCN, SiON, SiOCN, or other suitable dielectric material. In some embodiments, the dielectric liners 222 may include dielectric constant about 4.0≤k≤4.5. The thickness of each dielectric liner 222 is in a range from about 10 Å to about 40 Å. The dielectric liners 222 may prevent metal diffusion from the conductive features 201. The dielectric liners 222 can be deposited with, a PECVD, a flowable CVD process, or other suitable deposition processes. In other embodiments, the dielectric liners 222 may be formed using thermal ALD process to prevent damage to the inhibitors 150. In some embodiments, deposition temperature of the ALD process may be less than 400 C with step coverage over 90%.

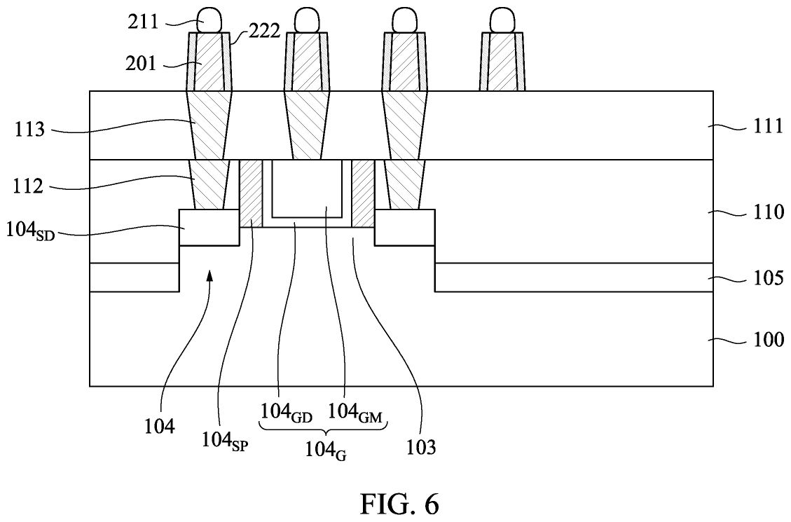

Reference is made to FIG. 6. An etching process is performed to remove the inhibitors 150, so as to expose surfaces of the hard masks 211 and the second ILD layer 111. After the inhibitors 150 are removed, top surface and sidewalls of each of the hard masks 211 are exposed, and portions of top surface of the second ILD layer 111 are exposed. In some embodiments, the etching process may include dry etching, such as plasma etching.

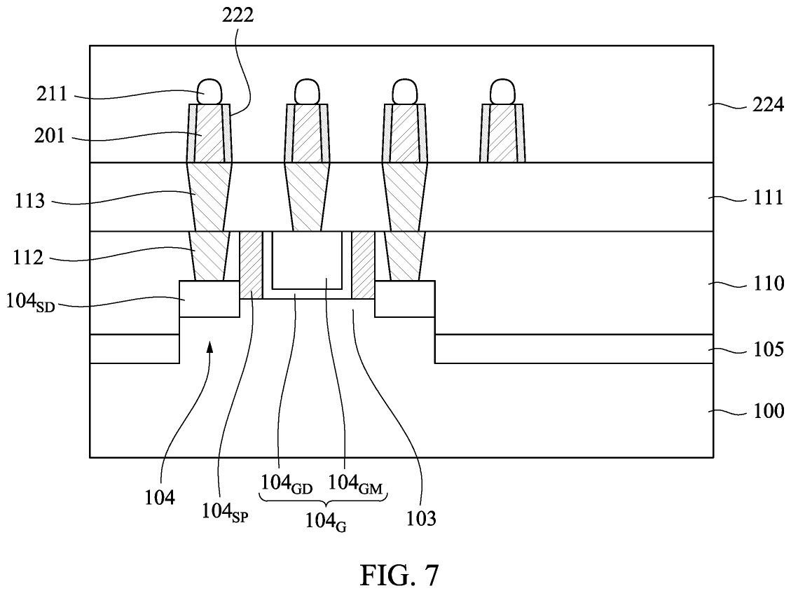

Reference is made to FIG. 7. An inter-metal dielectric (IMD) layer 224 is formed overfilling the spaces adjacent to the conductive features 201, and laterally surrounding the conductive features 201. The IMD layer 224 may be in contact with portions of top surface of the second ILD layer 111. In some embodiments, bottom surface of the IMD layer 224 may be substantially level with bottom surfaces of the dielectric liners 222, and top surface of the IMD layer 224 may be substantially level with top surfaces of the dielectric liners 222. That is, the IMD layer 224 and the dielectric liners 222 may include substantially a same height. In some embodiments, the IMD layer 224 is spaced apart from the conductive features 201 through the dielectric liners 222.

In some embodiments, the IMD layer 224 may be formed of a low-k dielectric material that includes a lower dielectric constant than the dielectric liners 222. Accordingly, the IMD layer 224 can also be referred to as a low-k dielectric layer. Exemplary low-k dielectric material may include hydrogen doped silicon oxycarbide (SiOC:H). In some embodiments where the IMD layer 224 is made of hydrogen doped silicon oxycarbide (SiOC:H), the dielectric constant of the IMD layer 224 is about 2.6≤k≤3.3. The IMD layer 224 can be deposited with a high-density plasma CVD (HDPCVD), a PECVD process, ALD process, a plasma enhanced ALD (PEALD) process, spin coating, flowable CVD, or other suitable deposition processes.

As mentioned above, because the dielectric liners 222 are selectively formed on the conductive features 201, and thus the exposed surfaces of the hard masks 211 are free of coverage by the dielectric liners 222, which in turn will enlarge the opening between adjacent two of the hard masks 211, and will further reduce the aspect ratio of the space between adjacent two of the conductive features 201 (and hard masks 211). For example, the trench opening between adjacent two hard masks 211 is in a range from about 10 nm to about 20 nm, and the aspect ratio of the trench opening is in a range from about 3:1 to about 6:1. The thickness of each dielectric liner 222 is in a range from about 10 Å to about 40 Å, which will reduce trench opening by about 2 nm to 8 nm. As a result, the reduced aspect ratio may be beneficial for gap filling of the IMD layer 224, and the resulting IMD layer 224 may be formed having better film quality and without void/seam formation.

However, if the inhibitors 150 are omitted, the dielectric liners 222 may be formed lining the top surface and sidewalls of each hard mask 211, and will increase the aspect ratio of the space between adjacent two of the conductive features 201 (and hard masks 211). In such condition, the high aspect ratio may result in worse gap-filling, and may cause the IMD layer 224 having poor film quality and/or void/seam formation, and may also cause time dependent dielectric breakdown (TDDB) and/or mechanical issue.

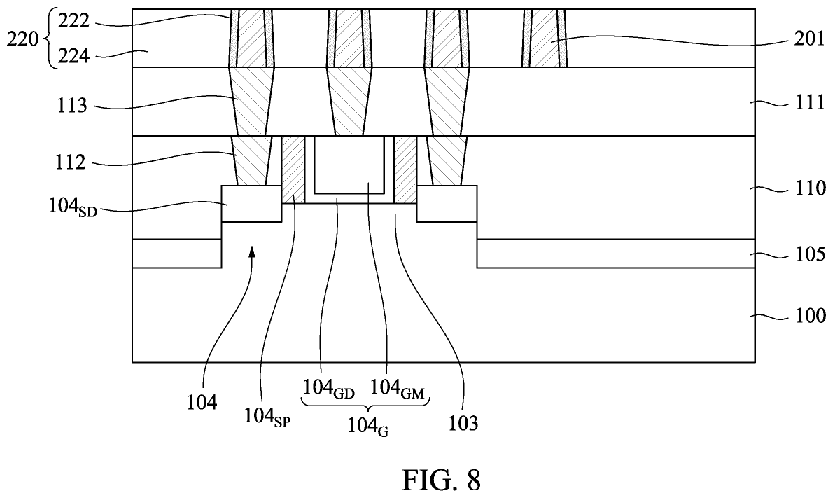

Reference is made to FIG. 8. A planarization process, such as a chemical mechanical polishing (CMP), is performed to remove excess material of the IMD layer 224 until the conductive features 201 are exposed. As a result, top surfaces of the conductive features 201, top surfaces of the dielectric liners 222, and top surface of the IMD layer 224 are coplanar with each other. In some embodiments, the hard masks 211 are removed during the planarization process.

After the planarization process is complete, the IMD layer 224 and the dielectric liners 222 can be collective referred to as a dielectric structure 220. As discussed above, because the inhibitors 150 are formed on top surface of the second ILD layer 111, the dielectric liners 222 may not be formed on the top surface of the second ILD layer 111. As a result, during the gap filling process of the IMD layer 224 as discussed in FIG. 7, the trench bottom is free of the dielectric liners 222, and thus the IMD layer 224 can be formed filling the trench bottom and in contact with the second ILD layer 111. As mentioned above, the IMD layer 224 is made of a low-k dielectric material. Accordingly, the capacitance of the dielectric structure 220 can be reduced as there are no dielectric liners 222 under the IMD layer 224. However, if the inhibitors 150 are omitted, the dielectric liners 222 may be formed lining top surface of the second ILD layer 111, and thus dielectric liners 222 may be present under the IMD layer 224. The additional portions of the high-k dielectric liners 222 may unwantedly increase the capacitance of the dielectric structure 220, and may inversely affect the device performance.

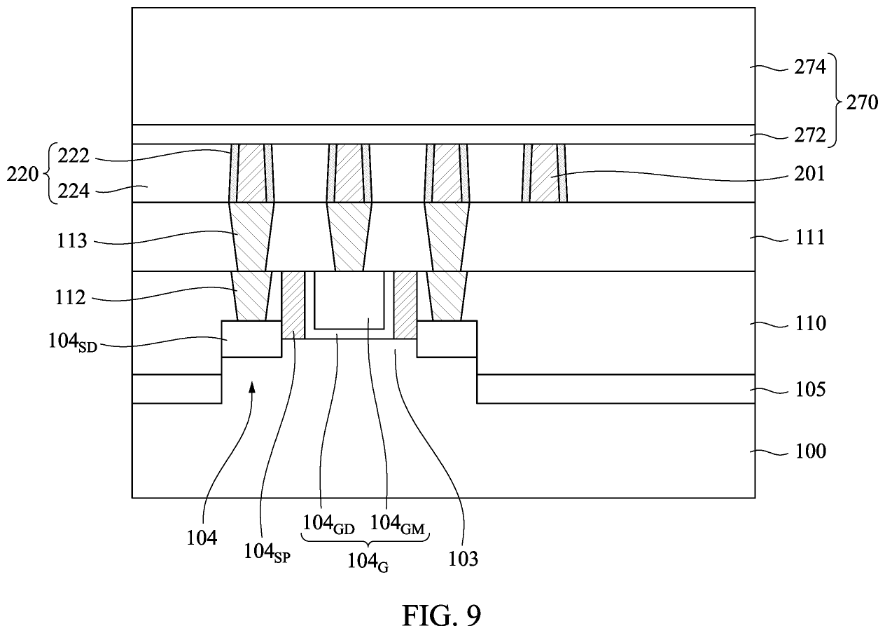

Reference is made to FIG. 9. An etch stop layer 272 and an IMD layer 274 are formed sequentially over the dielectric structure 220. In some embodiments, the etch stop layer 272 includes one or more insulator layers (e.g., SiN, SiC, SiCN, SiCO, CN, combinations thereof, or the like) having an etch rate different than an etch rate of an overlying IMD layer 274. In some embodiments, the IMD layer 274 may include silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The etch stop layer 272 and the IMD layer 274 may be deposited using suitable method, such as CVD, physical vapor deposition (PVD), ALD, PEALD, PECVD, SACVD, FCVD, spin-on, and/or the like, or a combination thereof. In some embodiments, the etch stop layer 272 and the IMD layer 274 may be collectively referred to as dielectric structure 270. In some embodiments, the etch stop layer 272 is thinner than the IMD layer 274 along the vertical direction.

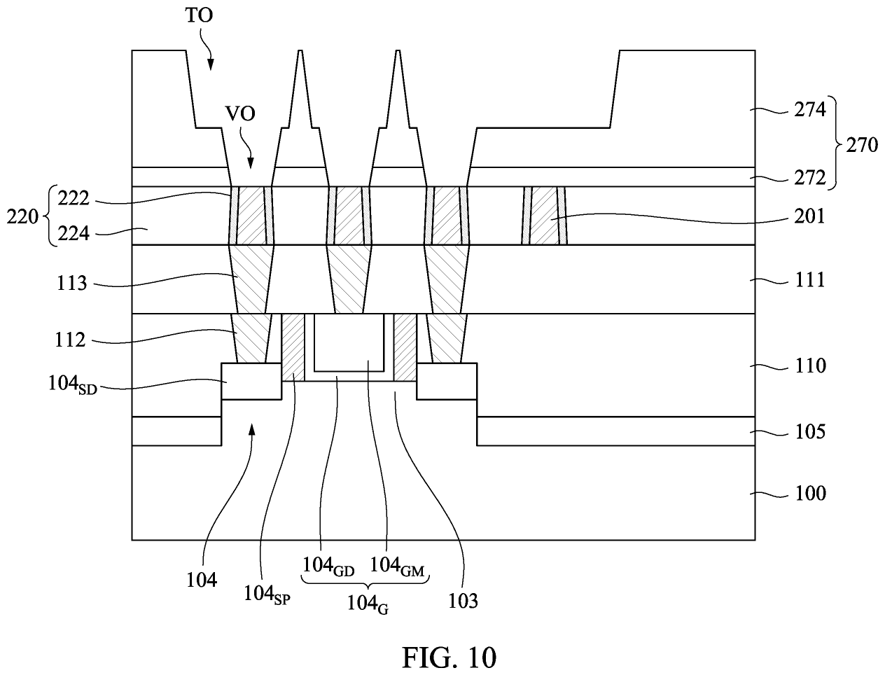

Reference is made to FIG. 10. The dielectric structure 270 is formed with a dual damascene opening including trench openings TO and via openings VO, in which each trench opening TO is above and in spatial communication with one or more via openings VO. In some embodiment, a dual damascene techniques may include a “via-first” patterning method or a “trench-first” patterning method, and the trench openings TO and the via openings VO may be formed using a typical lithographic with masking technologies and anisotropic etch operation (e.g., plasma etching or reactive ion etching). Although the embodiments illustrate dual damascene openings in the dielectric structure 270, single damascene processing may also be employed.

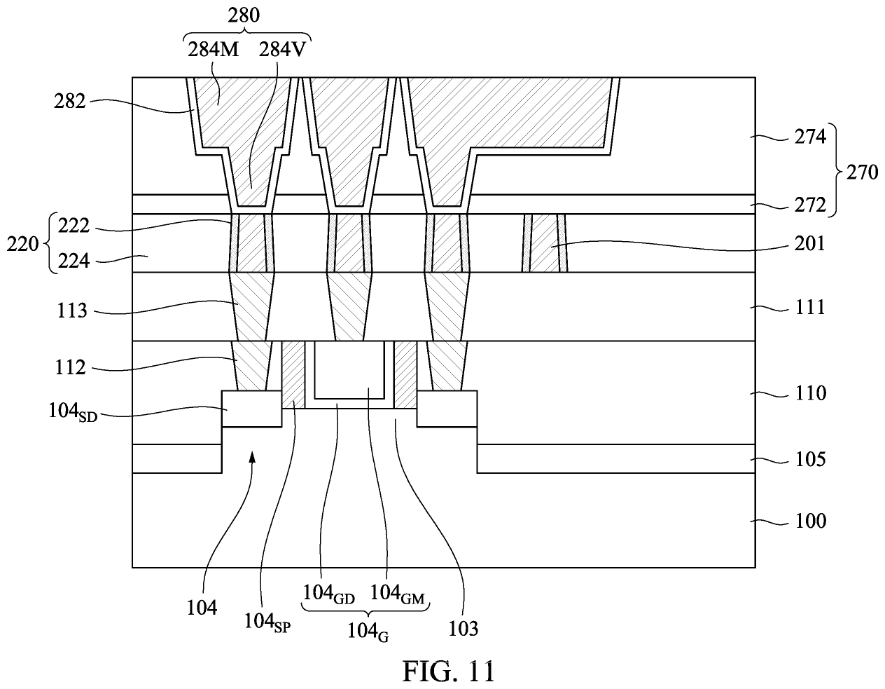

Reference is made to FIG. 11. Barrier layers 282 are deposited lining the trench openings TO and the via openings VO. Conductive features 284 are deposited in the trench openings TO and the via openings VO, and over the barrier layers 282, and overfilling the trench openings TO. In some embodiments, the barrier layers 282 may include barrier materials such as titanium (Ti), titanium nitride (TiN), tantalum (Ta), tantalum nitride (TaN), and combinations thereof, and can be formed using CVD, ALD, PVD, or the like. In some embodiments, material of the conductive features 284 may include metal, such as copper or copper alloys, or other suitable conductive materials, such as silver, gold, tungsten, aluminum, or other suitable materials, and can be formed using CVD, ALD, PVD, or the like. In some embodiments, the barrier layer 282 may be omitted.

Then, a planarization process, such as CMP, is performed to remove excess materials of the barrier layers 282 and the conductive features 284. After the CMP process is complete, each of the conductive features 284 has a portion in the via openings VA and a portion in the trench openings TO. In some embodiments, the portion of the conductive feature 284 in the via opening VA can be referred to as via portion 284V that serve as metal via to conduct current vertically between different interconnect levels, while the portion of the conductive feature 284 in the trench opening TO can be referred to as metal line portion 284M that serve as metal line to conduct current laterally and distribute electrical signals and power within a same level.

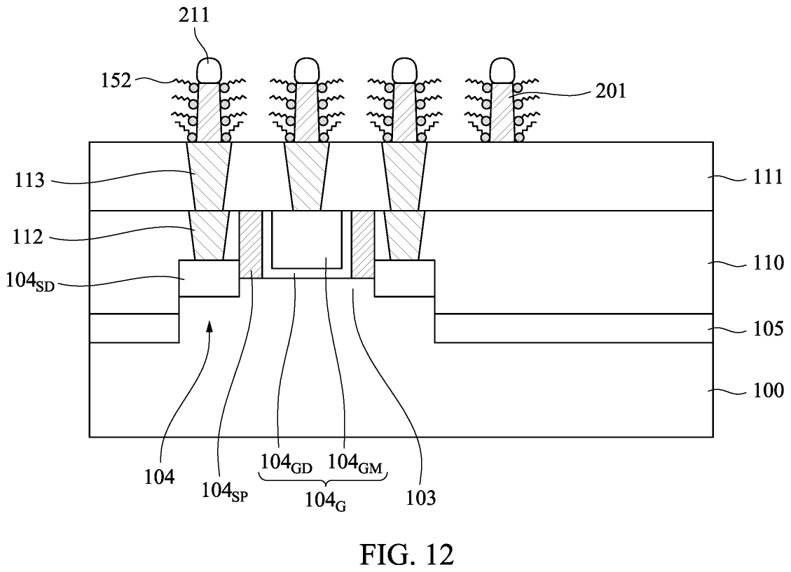

FIGS. 12 to 14 illustrate a method in various stages of forming a semiconductor device in accordance with some embodiments of the present disclosure. It is noted that some elements of FIGS. 12 to 14 are similar to those described with respect to FIGS. 1 to 11, such elements are labeled the same, and relevant details will not be repeated for brevity.

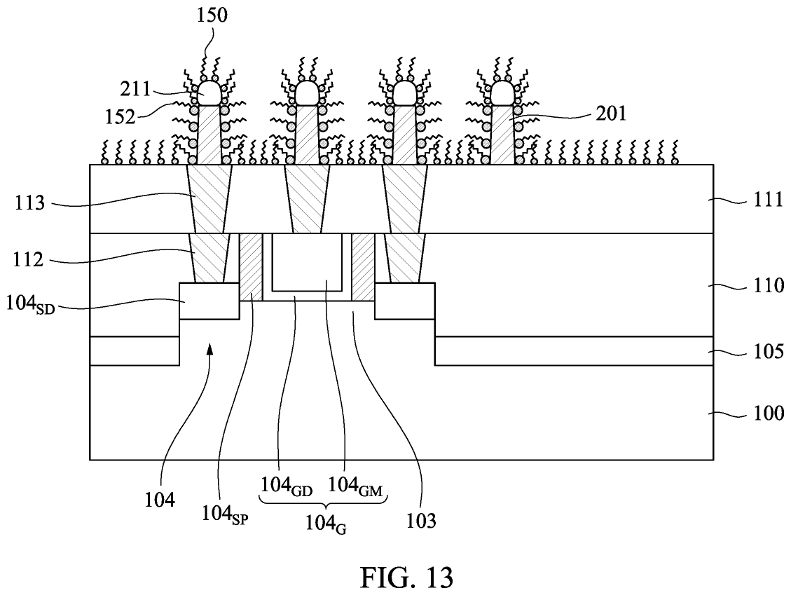

Reference is made to FIG. 12. A first surface passivation process is performed to the structure shown in FIG. 3. In greater detail, the first surface passivation process is performed to the exposed surfaces of the conductive features 201. In greater detail, the first surface passivation process is performed such that the exposed surfaces of the conductive features 201 are passivated, while the exposed surfaces of the hard masks 211 and the second ILD layer 111 may remain un-passivated. In some embodiments, the first surface passivation process includes forming inhibitors 152 on the exposed surfaces of the conductive features 201, while the exposed surfaces of the hard masks 211 and the second ILD layer 111 may be free of coverage by the inhibitors 152. That is, after the first surface passivation process is complete, the surfaces of the hard masks 211 and the second ILD layer 111 remain exposed. The inhibitors 152 may be used to suppress growth rate of a material of another inhibitor formed in later steps (e.g., the inhibitors 150 in FIG. 13), and will be discussed later. In some embodiments, the inhibitors 152 may be formed by vapor phase deposition, such as CVD, or by wet deposition process, such as spin coating, spray, dip coating, or other suitable deposition process.

In some embodiments, the inhibitors 152 may include a first self-assembled-monolayer (SAM). For example, the first SAM may include phosphonic, carboxylic, alkyne, thiol . . . etc head group that can selective grown on metal surface. That is, the first SAM can be selectively formed on a metal surface (e.g., the conductive features 201), but may not be formed on a dielectric surface (e.g., the hard masks 211 and the second ILD layer 111). Stated another way, the first SAM may include higher growth rate on a metal surface than on a dielectric surface.

Reference is made to FIG. 13. A second surface passivation process is performed to the exposed surfaces of the hard masks 211 and the second ILD layer 111. In greater detail, the surface passivation process is performed such that the exposed surfaces of the hard masks 211 and the second ILD layer 111 are passivated. In some embodiments, the second surface passivation process includes forming inhibitors 150 on the exposed surfaces of the hard masks 211 and the second ILD layer 111. On the other hand, the surfaces of the conductive features 201 are already coated with the inhibitors 152, and the inhibitors 152 may suppress the formation of the inhibitors 150. In some embodiments, the inhibitors 150 and the inhibitors 152 are made of different materials.

In some embodiments, the inhibitors 150 may include a second self-assembled-monolayer (SAM). For example, the second SAM may include silanol or silyl halide headgroup and hydrocarbon backbone that can selective grown on dielectric surface. That is, SAM can be selectively formed on a dielectric surface (e.g., the hard masks 211 and the second ILD layer 111).

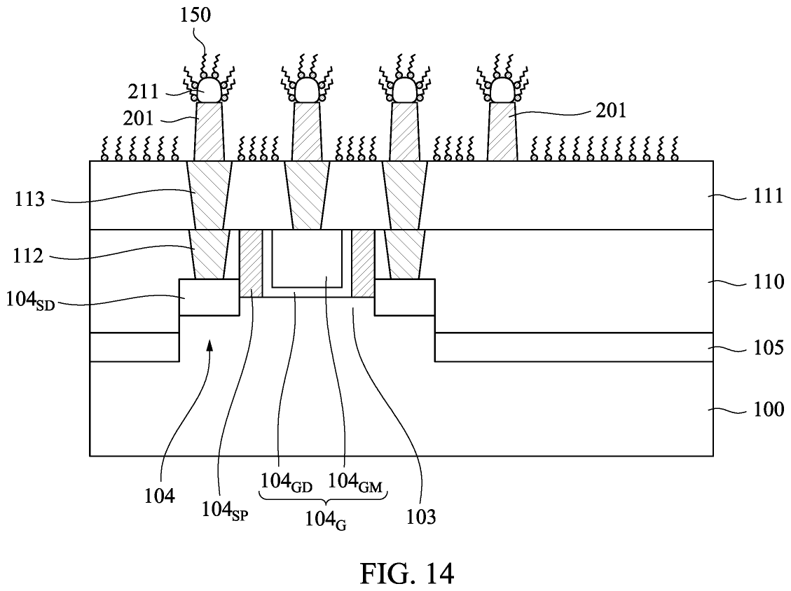

Reference is made to FIG. 14. The inhibitors 152 are removed, so as to expose surfaces of the conductive features 201. Once the inhibitors 152 are removed, the exposed surfaces of the conductive features 201 become un-passivated. The structure shown in FIG. 14 may undergo the processes discussed in FIGS. 5 to 11, and the resulting structure is shown in FIG. 11.

The inhibitors 152 may be removed using a thermal process or a wet etching process. In some embodiments where a bonding energy between the inhibitors 152 and the conductive features 201 is lower than a bonding energy between the inhibitors 150 and the hard masks 211/the second ILD layer 111, the inhibitors 152 may be removed using a thermal process. For example, an annealing process may be performed to break the dangling bonds between the inhibitors 152 and the conductive features 201 to remove the inhibitors 152 from the conductive features 201, while the dangling bonds between the inhibitors 150 and the hard masks 211/the second ILD layer 111 may remain. That is, the temperature of the annealing process may be high enough to break the dangling bonds between the inhibitors 152 and the conductive features 201, while the temperature may not break the dangling bonds between the inhibitors 150 and the hard masks 211/the second ILD layer 111. On the other hand, when the inhibitors 152 are removed using a wet etching process, the etchant may be selected such that the inhibitors 150 have higher etching resistance to the etching process than the inhibitors 152.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure include forming conductive features with hard masks atop over a dielectric layer. A surface passivation process is performed to the exposed surfaces of the hard masks and the dielectric layer. As a result, a dielectric on metal (DoM) deposition can be achieved to form dielectric liners on opposite sidewalls of each conductive feature. The selective deposition of the dielectric liners may enlarge trench opening for better gap-fill quality/reliability and replace trench bottom liner by low-k dielectric for capacitance improvement.

In some embodiments of the present disclosure, a method includes forming a metal layer over a dielectric layer; forming hard masks over the metal layer; etching the metal layer using the hard masks as etch mask to form metal features; selectively forming dielectric liners on opposite sidewalls of each of the metal features, while leaving surfaces of the hard masks and the dielectric layer exposed by the dielectric liners; and forming an inter-metal dielectric layer laterally surrounding the metal features.

In some embodiments, the method further includes performing a passivation process to passivate the surfaces of the hard masks and the dielectric layer prior to selectively forming the dielectric liners on the opposite sidewalls of each of the metal features, in which the passivated surfaces of the hard masks and the dielectric layer suppress a growth rate of the dielectric liners.

In some embodiments, performing the passivation process comprises forming a self-assemble monolayer (SAM) on the surfaces of the hard masks and the dielectric layer, and in which the method comprises removing the SAM after the dielectric liners are formed.

In some embodiments, the inter-metal dielectric layer is in contact with a top surface of the dielectric layer.

In some embodiments, the inter-metal dielectric layer is spaced apart from the metal features through the dielectric liners.

In some embodiments, a bottom surface of the inter-metal dielectric layer is substantially level with bottom surfaces of the dielectric liners.

In some embodiments, the method further includes performing a planarization process on the inter-metal dielectric layer until the metal features are exposed.

In some embodiments of the present disclosure, a method includes forming a metal layer over a dielectric layer; forming hard masks over the metal layer; etching the metal layer using the hard masks as etch mask to form metal features; performing a first surface passivation process to form first inhibitors on surfaces of the hard masks and the dielectric layer, while leaving surfaces of the metal features free of coverage by the first inhibitors; forming dielectric liners on the surfaces of the metal features; and forming an inter-metal dielectric layer laterally surrounding the metal features.

In some embodiments, the method further includes removing the first inhibitors after the dielectric liners are formed.

In some embodiments, the method further includes prior to performing the first surface passivation process, performing a second surface passivation process to form second inhibitors on the surfaces of the metal features, while leaving the surfaces of the hard masks and the dielectric layer free of coverage by the second inhibitors; and removing the second inhibitors after the first surface passivation process is complete.

In some embodiments, the first inhibitors and the second inhibitors are made of different materials.

In some embodiments, the first inhibitors comprises silanol or silyl halide headgroup, and the second inhibitors comprises phosphonic, carboxylic, alkyne, thiol head group.

In some embodiments, the inter-metal dielectric layer has a lower dielectric constant than the dielectric liners.

In some embodiments, a bottom surface of the inter-metal dielectric layer is free of coverage by the dielectric liners.

In some embodiments, each of the metal features includes a trapezoid cross-sectional profile.

In some embodiments of the present disclosure, a semiconductor device includes a substrate. A transistor is over the substrate. An interlayer dielectric layer is over the transistor. An inter-metal dielectric layer is over and in contact with the interlayer dielectric layer. A conductive feature extends through the inter-metal dielectric layer. Dielectric liners are on opposite sidewalls of the conductive feature.

In some embodiments, the conductive feature is spaced apart from the inter-metal dielectric layer through the dielectric liners.

In some embodiments, a dielectric constant of the inter-metal dielectric layer is lower than a dielectric constant of the dielectric liners.

In some embodiments, the dielectric liners and the inter-metal dielectric layer have substantially a same height.

In some embodiments, the conductive feature includes a trapezoid cross-sectional profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a metal layer over a dielectric layer;
forming hard masks over the metal layer;
etching the metal layer using the hard masks as etch mask to form metal features;
selectively forming dielectric liners on opposite sidewalls of each of the metal features, while leaving surfaces of the hard masks and the dielectric layer exposed by the dielectric liners; and
forming an inter-metal dielectric layer laterally surrounding the metal features.

2. The method of claim 1, further comprising performing a passivation process to passivate the surfaces of the hard masks and the dielectric layer prior to selectively forming the dielectric liners on the opposite sidewalls of each of the metal features, wherein the passivated surfaces of the hard masks and the dielectric layer suppress a growth rate of the dielectric liners.

3. The method of claim 2, wherein performing the passivation process comprises forming a self-assemble monolayer (SAM) on the surfaces of the hard masks and the dielectric layer, and wherein the method comprises removing the SAM after the dielectric liners are formed.

4. The method of claim 1, wherein the inter-metal dielectric layer is in contact with a top surface of the dielectric layer.

5. The method of claim 1, wherein the inter-metal dielectric layer is spaced apart from the metal features through the dielectric liners.

6. The method of claim 1, wherein a bottom surface of the inter-metal dielectric layer is substantially level with bottom surfaces of the dielectric liners.

7. The method of claim 1, further comprising performing a planarization process on the inter-metal dielectric layer until the metal features are exposed.

8. A method, comprising:
forming a metal layer over a dielectric layer;
forming hard masks over the metal layer;
etching the metal layer using the hard masks as etch mask to form metal features;
performing a first surface passivation process to form first inhibitors on surfaces of the hard masks and the dielectric layer, while leaving surfaces of the metal features free of coverage by the first inhibitors;
forming dielectric liners on the surfaces of the metal features; and
forming an inter-metal dielectric layer laterally surrounding the metal features.

9. The method of claim 8, further comprising removing the first inhibitors after the dielectric liners are formed.

10. The method of claim 8, further comprising:
prior to performing the first surface passivation process, performing a second surface passivation process to form second inhibitors on the surfaces of the metal features, while leaving the surfaces of the hard masks and the dielectric layer free of coverage by the second inhibitors; and
removing the second inhibitors after the first surface passivation process is complete.

11. The method of claim 10, wherein the first inhibitors and the second inhibitors are made of different materials.

12. The method of claim 11, wherein the first inhibitors comprises silanol or silyl halide headgroup, and the second inhibitors comprises phosphonic, carboxylic, alkyne, thiol head group.

13. The method of claim 8, wherein the inter-metal dielectric layer has a lower dielectric constant than the dielectric liners.

14. The method of claim 8, wherein a bottom surface of the inter-metal dielectric layer is free of coverage by the dielectric liners.

15. The method of claim 8, wherein each of the metal features includes a trapezoid cross-sectional profile.

16. A semiconductor device, comprises:
a substrate;
a transistor over the substrate;
an interlayer dielectric layer over the transistor;
an inter-metal dielectric layer over and in contact with the interlayer dielectric layer;
a conductive feature extending through the inter-metal dielectric layer; and
dielectric liners on opposite sidewalls of the conductive feature.

17. The semiconductor device of claim 16, wherein the conductive feature is spaced apart from the inter-metal dielectric layer through the dielectric liners.

18. The semiconductor device of claim 16, wherein a dielectric constant of the inter-metal dielectric layer is lower than a dielectric constant of the dielectric liners.

19. The semiconductor device of claim 16, wherein the dielectric liners and the inter-metal dielectric layer have substantially a same height.

20. The semiconductor device of claim 16, wherein the conductive feature includes a trapezoid cross-sectional profile.
